(19) United States
(12) Patent Application Publication
(10) Pub. No.: US 2013/0307549 A1
(43) Pub. Date: Nov. 21, 2013

(54) INSTRUMENT FOR MEASURING LED LIGHT SOURCE

(71) Applicant: FOXCONN TECHNOLOGY CO., LTD., New Taipei (TW)

(72) Inventor: TAY-JIAN LIU, New Taipei (TW)

(73) Assignee: FOXCONN TECHNOLOGY CO., LTD., New Taipei (TW)

(21) Appl. No.: 13/851,959

(22) Filed: Mar. 28, 2013

(30) Foreign Application Priority Data
May 18, 2012 (CN) 201210157273.8

(51) Int. Cl. G01J 1/02; G01R 31/44

(52) U.S. Cl. CPC G01J 1/0252; G01R 31/44
USPC 324/414

(57) ABSTRACT

A LED light source measuring instrument includes a shell portion and a test portion. The shell portion supports the test portion. The test portion includes a carrier plate for placing a LED light source to be tested. A conductive structure is set on the carrier plate for electrically connecting with an underside surface of the LED light source; a cooling chip is set on the carrier plate; a vacuum suction device is provided for generating a vacuum force on the test portion for securely attaching the LED light source to the carrier plate. The cooling chip is used for controlling the temperature of the LED light source within a limited range. A fan is provided for generating a cooling airflow to the LED light source. A heat sink fin extends from the carrier plate toward the fan.

### BACKGROUND

1. Technical Field

The present disclosure relates to a light emitting diode (LED) light source measuring instrument, and particularly relates to a LED positioned and fixed through vacuum force during measurement. The measuring instrument can provide constant temperature environment, without light blocking, easy operation and high precision, suitable for measuring any different sizes, shapes, structures and types of the LED.

2. Description of Related Art

An optical and electrical measuring system of LED light source is used by inserting a measuring instrument which carries a well-positioned LED light source into an integrating sphere; through connecting a peripheral spectrum analyzer, an electrical parameter measurement instrument and a LED power controller, the chromaticity coordinate, the color temperature, the color rendering index, the color tolerance adjustment, the wavelength, the color purity, the luminous flux, the voltage, the current and the power, etc., of the LED light source can be detected. The typical LED light source used for the lighting fixture is the surface mounted technology (SMT) type LED, which is suitable for mass production. But there are many differences among the SMT LED light sources regarding the sizes, shapes, structures and types.

The electrode plates of the LED light source 203 for connecting with the power source as shown in FIG. 1 include a base positive electrode plate 2032 and a base negative electrode plate 2033 connecting with a backside of the LED light source 203 which is opposite to the light emitting surface 2031 of the LED light source 203; a longitudinal positive electrode plate 2132 and a longitudinal negative electrode plate 2133 are extending toward the longitudinal direction; a lateral positive electrode plate 2232 and a lateral negative electrode plate 2233 continue extending toward the lateral direction and parallel with the base positive and negative electrode plates 2032, 2033. In other prior arts they do not have the structure with the lateral positive electrode plate 2232 and the lateral negative electrode plate 2233. Due to the miniaturization trend and cost considerations, manufacturers only provide the SMT LED light source with the base positive and negative electrode plates 2032, 2033. Also, since the test environment lacks temperature control, the measured LED light source 203 always stay in the transient state of temperature rise. Thus cannot clearly define the long-term stability of the steady state test conditions, resulting in the test data lack of reproducibility. Especially for the power type LED with power more than 0.5 watts which is commonly used in lighting industry. Due to a lack of the thermal design or improper design of the prior art measuring instrument, the LED light source 203 may far exceed the allowable temperature limit because of the rapid temperature rising, and damage the LED light source 203, rendering the measurement result totally meaningless.

In prior art, the measuring instrument of LED light source can be divided into two types, a pressed-type measuring instrument 1a shown in FIG. 2, and a pushed-type measuring instrument 1b shown in FIG. 3. The pressed-type measuring instrument 1a includes a shell portion 10a made of a metal material in a hollow cylinder shape, and a testing portion 20a located at the opening end of the shell portion 10a. The size of an upper stage section 101a is matched with the entrance of the integrating sphere. The testing portion 20a is installed into the integrating sphere, then positioned by a stepped surface 103 which is located between the upper stage section 101a and a rear section 102a. The testing portion 20a is made of a non-metallic carrier plate 201a which is fixedly arranged at the opening end of the shell portion 10a; a pressed seat 301 is fixed on the carrier plate 201a, wherein the pressed seat 301 is made of metallic materials. A metal position adjustable bolt 302 is arranged on the pressed seat 301 along the radial direction. The nuts of the adjustable bolts 302 are connected with the different polarity power source, become as a positive electrode 205a and a negative electrode 210a which supply the power to the LED light source 203. A supporting seat 303 is arranged inside the shell portion 10a and supports an axial spring member 304. An inverted U-shaped top plate 305 is on the top of the axial spring member 304, and moves upward by spring expansion. The top plate 305 is limited and can only slide axially through the size matching between the cylindrical wall of the top plate 305 and the wall surface of the central through hole of the carrier plate 201a. The central region of the end surface of the top plate 305 is the electrically insulating under test zone.

When the pressed-type measuring instrument 1a is not placed with the LED light source 203, the end surface of the top plate 305 directly contact with the positive and negative electrodes 205a, 210a of the adjustable bolts 302. When operating, the LED light source 203 is placed on the pressed-type measuring instrument 1a, first; then the top plate 305 is pressed to adjust the position of the positive and negative electrodes 205a, 210a according to the size of the lateral positive and negative electrode plates 2232, 2233 of the LED light source 203, according to FIG. 1. The LED light source 203 is thus placed in the under test zone of the top plate 305, and makes the positive and negative electrodes 205a, 210a of the measuring instrument 1a compressing the corresponding lateral positive and negative electrode plates 2232, 2233 of the LED light source 203, respectively. To achieve the under test state, the LED light source 203 is sandwiched between the top plate 305 and the pair of electrodes 205a, 210a of the adjustable bolt 302.

Since the pressed seat 301, the adjustable bolts 302 and the pair of electrodes 205a, 210a of the pressed-type measuring instrument 1a are necessarily arranged above the light emitting surface 2031 of the LED light source 203, serious light blocking will further underestimate the measured luminous flux value, and the application of the pressed-type measuring instrument 1a is limited only in a few of the lateral positive and negative electrode plates 2232,2233 of the LED light source 203. Using this measuring instrument 1a to measure different sizes and shapes of LED light source 203 has its limitation and operating inconvenient, particularly in the non-temperature controlled test environment, resulting in the lack of reproducibility of measurement data, even causing the damage of the LED light source 203. Thus, the pressed-type measuring instrument 1a has serious limitations and shortcomings in both measuring quality and application level.

FIG. 3 shows the pushed-type measuring instrument 1b. The main differences between the pressed-type and pushed-type measuring instruments 1a, 1b are that: There is a flat shallow trench 412 through a center of a carrier plate 201b; the bottom of a negative electrode assembly 402 is fixed inside the trench 412; a positive electrode assembly 401 can slide freely along the trench 412; the positive and negative electrode assemblies 401, 402 are made of electrically insulating material. Two metal thimbles 205b, 210b extend respectively from the positive and negative electrode assemblies 401, 402 toward the LED light source 203. The two metal thimbles 205b, 210b are used to electrically connect with a power source thereby making the two metal thimbles 205b, 210b form a pair of positive and negative electrodes 205b, 210b for the pushed-type measuring instrument 1b.

The movement of the positive electrode assembly 401 is along a long trench 409 which opens through the carrier plate 201b to communicate with the trench 412. A spring member 404 is arranged inside a shell portion 10b by a screw passing through the long trench 409 to connect with the positive electrode assembly 401 so that the positive electrode assembly 401 is fixed to a slider 405. The slider 405 is in the middle of the spring member 404. One side of the slider 405 along the radial direction has a guide rod 406, the end of the guide rod 406 is extending to but no over the outer wall surface of an upper stage section 101b. The other side of the slider 405 along the radial direction locates a fixing screw 407 which extends through the upper stage section 101b, and allows a spring 408 extend into a corresponding blind hole of the slider 405. The blind hole, the guide rod 406 and the fixing screw 407 are coaxially aligned. When operating the pushed-type measuring instrument 1b, gently push a certain distance of the guide rod 406 to enable the slider 405 sliding along the trench 412, making the positive electrode assembly 401 moving the same distance away from the fixed negative electrode assembly 402 to place the LED light source 203 properly between the electrode assemblies 401, 402. When the pushed force on the guide rod 406 is released, the positive electrode assembly 401 moves close to the LED light source 203 to electrically engage the longitudinal positive electrode plate 2132.

According to the size of the LED light source 203, the positive and negative electrodes 205b, 210b of the positive and negative electrodes assembly 401, 402 of the pushed-type measuring instrument 1b contact with and supply power to the longitudinal positive and negative electrode plates 2132, 2133 of the LED light source 203. However, the heights of the positive and negative electrode assemblies 401, 402 of the pushed-type measuring instrument 1b and the longitudinal positive and negative electrode plates 2132, 2133 of the LED light source 203 are fixed and may not match each other. Additionally, the amount of the displacement of the slider 405 is limited via pushing the guide rod 406, the size of the LED light source 203 is varied in the market, and the LED light source 203 may not have the longitudinal positive and negative electrode plates 2132, 2133. Therefore, using the same pushed-type measuring instrument 1b to measure different sizes and shapes of the LED light source 203 has its limitation. The pushed-type measuring instrument 1b is only suitable for the type of the LED light source 203 with the longitudinal electrode plates 2131, 2133. Particularly in the non-temperature controlled test environment where the steady-state test conditions cannot be clearly defined. Thus, the pushed-type measuring instrument 1b has its limitations and shortcomings in measuring quality and the application level.

In order to reduce the impact of the temperature rise during the measurement process, the current market has pulsed DC power supply for measuring the LED light source 203, and claimed that the measuring instrument can retrieve the transient data of the optical and electrical parameters within a fraction of a second after lighting the LED light source 203. However, any heat sources including the LED light source 203 in the initial temperature rise transient process must be the fastest and most dramatic particular in the power type LED. After a long-term experimental confirmation, under the test conditions which do not result in the damage of the LED light source 203, evidenced that the initial luminous flux of these transient data are up more than double that of the long-term stability of the steady state flux data. The transient flux data show very big differences at different time instants for initial lighting and lose the reproducibility when detecting the same LED light source 203, resulting in only the LED manufactures strongly advocate and provide such transient data to the end users. However, for the LED lighting industry, the useful reference value should pay attention to the long-term steady state lighting performance. The initial transient data provided by the vendors are completely meaningless. The standardization of the LED light source 203 measurement method (CIE 127: 2007, MEASUREMENT OF LEDS) indicated that the above initial transient data must be clearly correlated to the steady state data, but the correlation will be different with different manufactures of LEDs. For the majority of the lighting applications, end users are completely unable to understand the meaning of the norms of transient data; therefore, the transient data of the LED light source 203 lack the practicability. Accordingly, measurement of the LED light source 203 still needs to be in line with the practical application and has long-term reproducibility and stable data.

Therefore, it is necessary to provide a way for non-destructive measurement of LED light source under the well-defined constant temperature steady state conditions, and the LED light source measuring instrument with no light blocking, easy operation, high precision and versatility.

### BRIEF DESCRIPTION OF THE DRAWINGS

Many aspects of the present LED light source measuring instrument can be better understood with reference to the following drawings. The components in the drawings are not necessarily drawn to scale, the emphasis instead being placed upon clearly illustrating the principles of the present LED light source measuring instrument. In the drawing, all the views are schematic.

FIG. 1 is a perspective view of a typical LED light source.

FIG. 2 is a schematic cross sectional view of a prior art measuring instrument for measuring the characteristics of the LED light source of FIG. 1.

FIG. 3 is a schematic cross sectional view of another prior art measuring instrument.

FIG. 4 is a schematic cross sectional view of a LED measuring instrument of the first embodiment of the present disclosure.

FIG. 5A is a top perspective view of a test portion of the LED measuring instrument of FIG. 4.

FIG. 5B is a bottom perspective view of the test portion of the LED measuring instrument of FIG. 4.

FIG. 6 is a schematic diagram of a telescopic assembly of the LED measuring instrument of FIG. 4.

FIGS. 7A and 7B are schematic diagrams of two kinds of electrodes of the LED measuring instrument of FIG. 4.

FIG. 8 is a schematic cross sectional view of a LED measuring instrument of the second embodiment of the present disclosure.

FIG. 9A is a top perspective view of a test portion of the LED measuring instrument of FIG. 8.

FIG. 9B is a bottom perspective view of the test portion of the LED measuring instrument of FIG. 8.

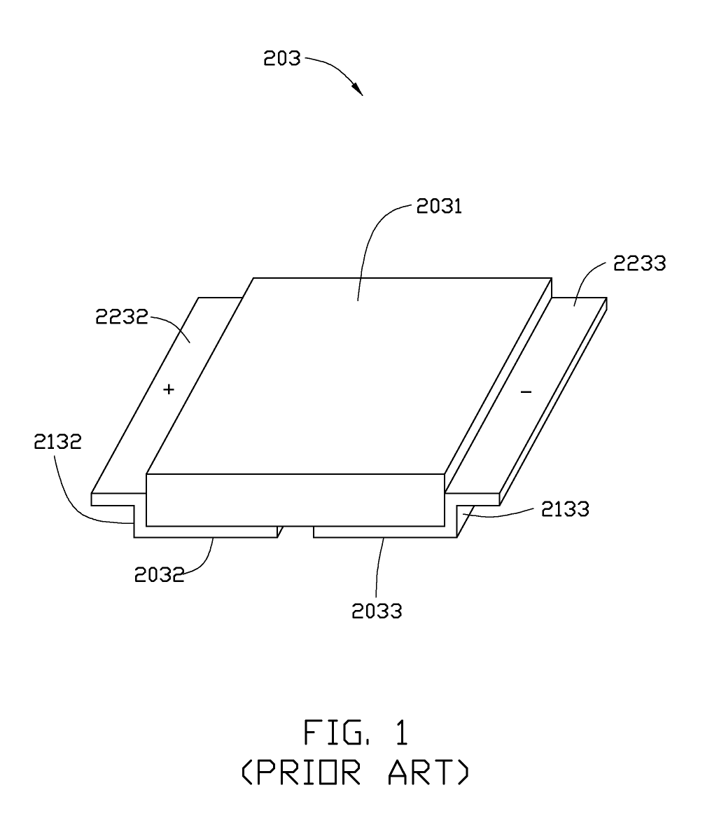

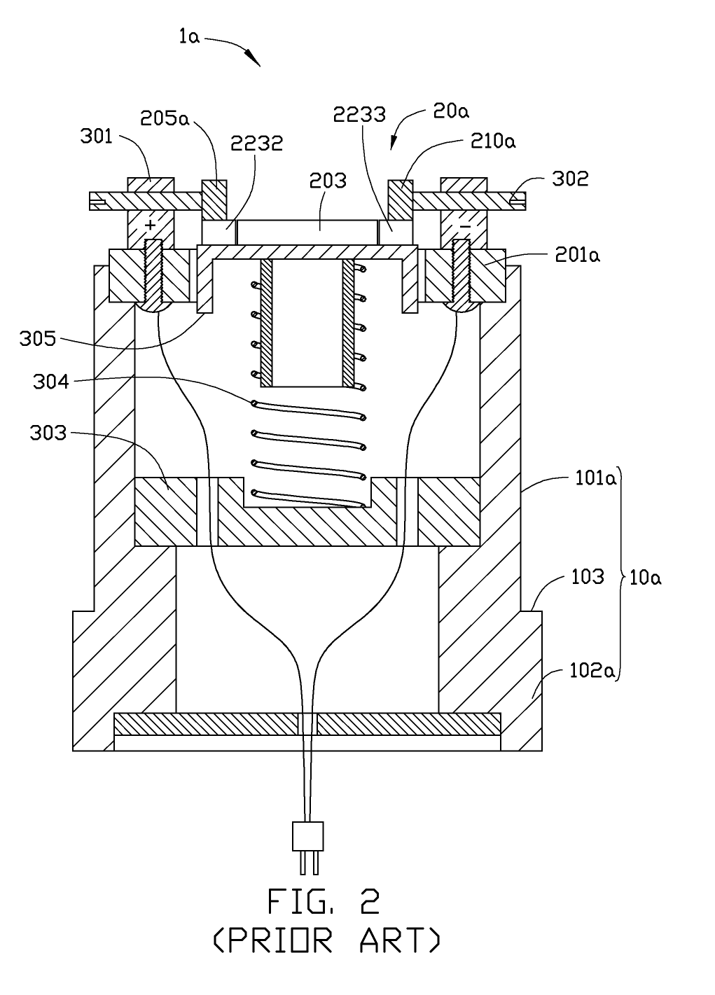

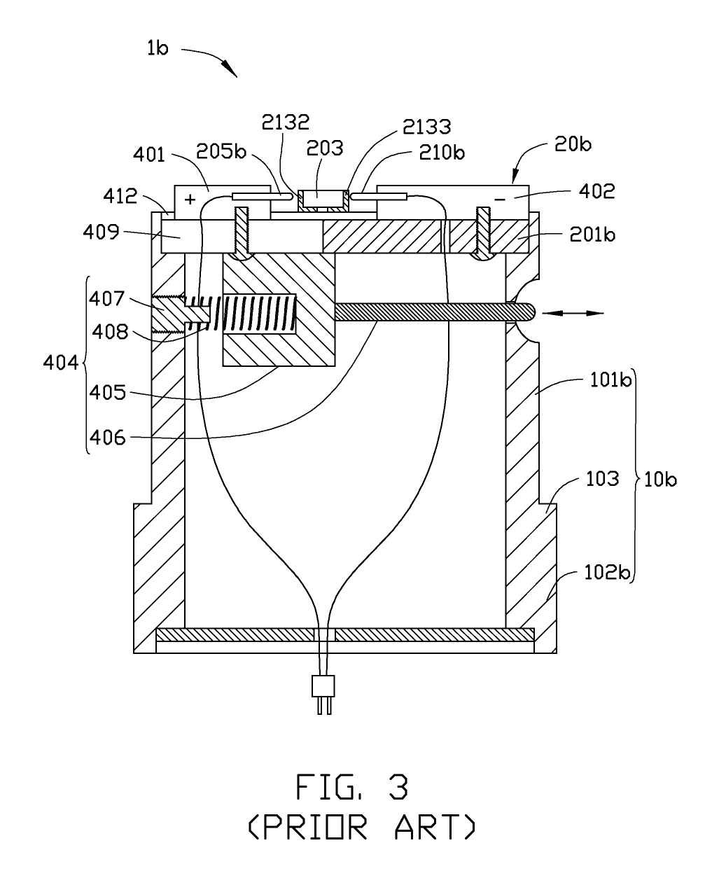

### DETAILED DESCRIPTION

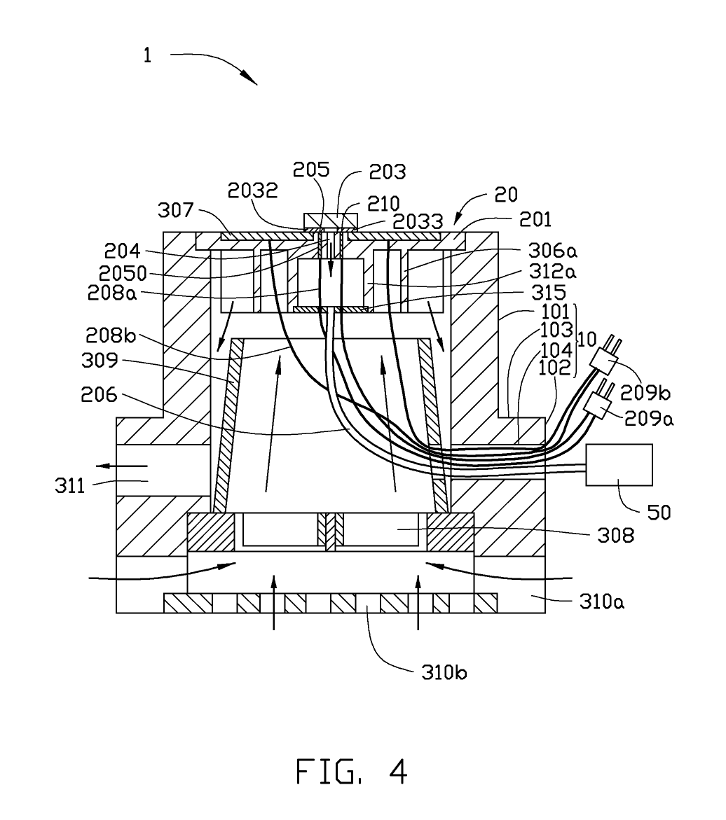

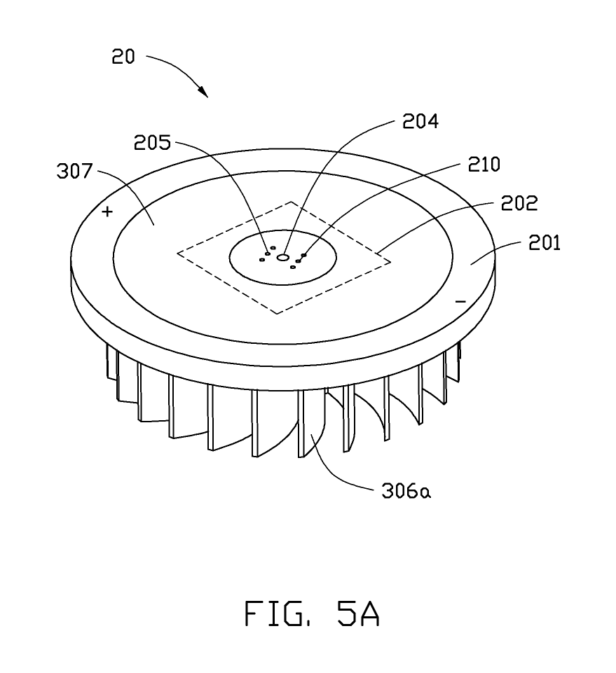

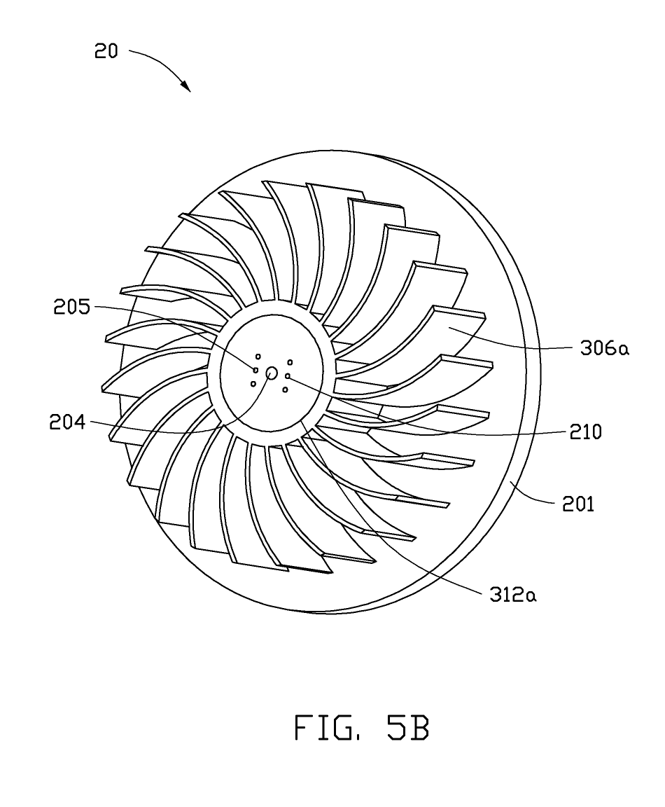

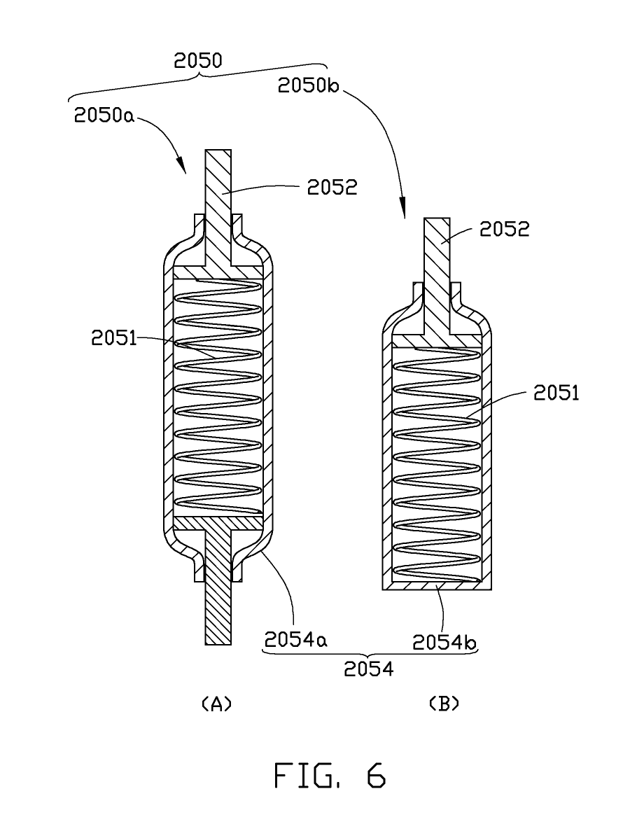

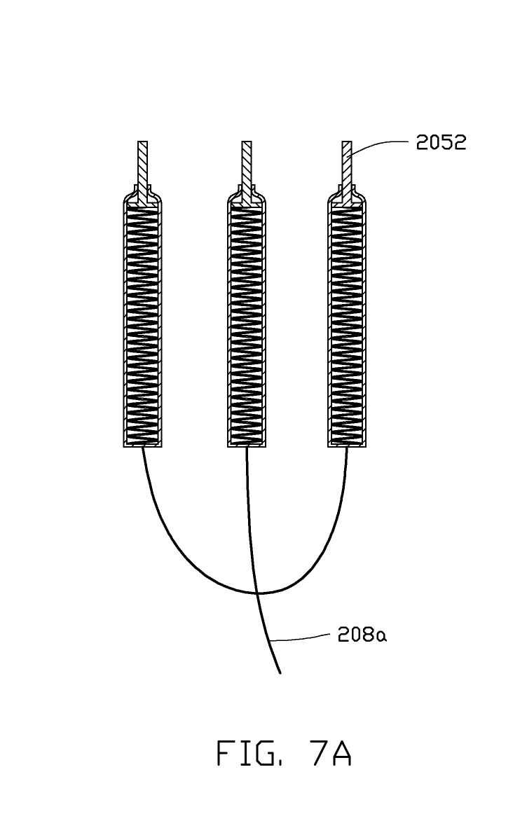

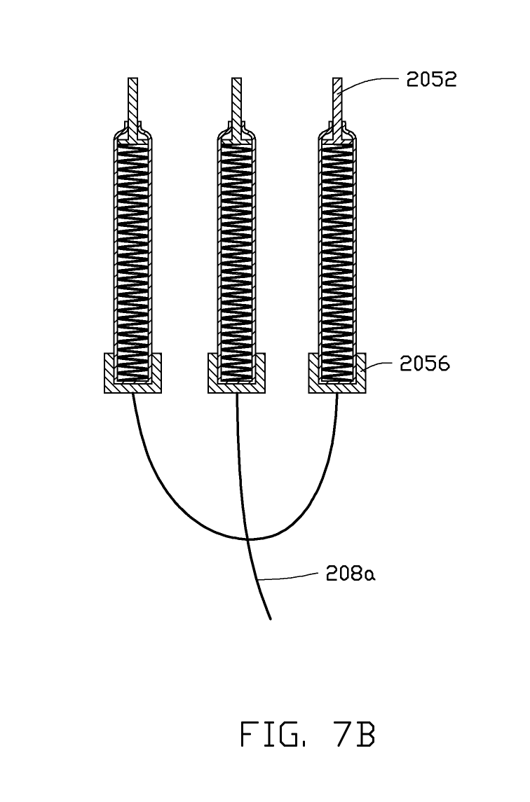

FIG. 4 is a schematic cross sectional view of a LED measuring instrument of the first embodiment of the present disclosure. FIGS. 5A and 5B are a top and a bottom perspective view of a test portion of the LED measuring instrument of FIG. 4, respectively. FIG. 6 is a schematic diagram of a telescopic assembly of the LED measuring instrument of FIG. 4. FIGS. 7A and 7B are schematic diagrams of two kinds of electrodes of the LED measuring instrument of FIG. 4. The measuring instrument includes a shell portion 10 and a test portion 20. The shell portion 10 is a hollow cylinder and has at least one side opening for receiving the test portion 20. The outer peripheral wall surface of the cylinder axially extending from the opening into a thinner upper stage section 101, and forms a right angle stepped surface 103 between the thinner upper stage section 101 and a thicker rear section 102. The outer peripheral wall size and shape of the upper stage section 101 match with the inner surrounding wall surface of the tubular entrance (not shown) of an integrating sphere (not shown). The stepped surface 103 abuts against the tubular end of the entrance, to achieve the test portion 20 inserted and positioned into the integrating sphere, so that the LED light source 203 is in under test status.

The test portion 20 includes a carrier plate 201 embedded in an opening end of the shell portion 10, and a heat sink fin 306a axially extending from a side of the carrier plate 201 opposite the LED light source 203 and toward the inside of the shell portion 10. The heat sink fin 306a is around the periphery of a central cylinder 312a, and extending radially with a plurality of spiral plates. The heat sink fin 306a enables the carrier plate 201 to increase heat dissipation area and enhance the heat conducting path, whereby heat generated by the LED light source 203 on the outer end surface of carrier plate 201 can be dissipated quickly. A space is defined between the end edge of the plurality of the spiral plate and the inner wall of the shell portion 10 for smoothing the path of the cooling airflow. The central cylinder 312a toward the opening end of the heat sink fin 306a has a cylinder lid 315. The center of the outer end surface of the carrier plate 201 is an electrically insulating under test zone 202 for placing the LED light source 203, with at least one air hole 204 at the center of the under test zone 202 passes through the carrier plate 201 and connects with a space surrounded by the central cylinder 312a.

In the present embodiment, it uses one air hole 204 for illustration. At least one pair of electrodes 205, 210 are located at a side of the carrier plate 201 exposed outwardly and positioned neighboring opposite sides of the air hole 204 for connecting with external control power (not shown) to conduct positive and negative voltages. FIG. 5A shows three pairs of electrodes 205, 210, wherein each pair of the electrodes 205, 210 is constituted by a metal sleeve 2054 (outer diameter less than 3 mm), inside the metal sleeve 2054 being equipped with a telescopic assembly 2050 of a metal spring 2051. One of a telescopic assembly 2050a is composed of a sleeve 2054a with two end openings, the spring 2051 is equipped inside the sleeve 2054a, and both ends of the spring 2051 are respectively connected to a thimble 2052 which is axially telescopic toward the corresponding opening of the sleeve 2054a, as shown in FIG. 6(A). Another telescopic assembly 2050b is composed of a sleeve 2054b with one end opening, the spring 2051 is equipped inside the sleeve 2054b and connected to a thimble 2052 which is axially telescopic toward the opening of the sleeve 2054b, as shown in FIG. 6(B). Each of the electrodes 205, 210 via the corresponding sleeve 2054 is perpendicularly extended and fixed in the corresponding pore of the carrier plate 201 and electrically insulating from the carrier plate 201. The pores are connected with the space surrounded by central cylinder 312a; one end of the thimble 2052 slightly protrudes upwardly beyond the surface of the under test zone 202 when the LED light source 203 is not placed on the under test zone 202.

Through a flexible tube 206, which is connected with the central cylinder 312a and fixed in the cylinder lid 315 and extends through a wall hole 104 passed through the rear section 102 of the shell portion 10, the air hole 204 is connected with the vacuum pump 50 outside the shell portion 10. The positive and negative electrodes 205, 210 are connected to an external control power supply (not shown) via two electric wires 208a using a plug 209a, to supply the power to the LED light source 203. One of the adopted ways, as shown in FIGS. 4 and 7A, the two electric wires 208a separately connected to the three thimbles 2052 at bottoms of the telescopic assemblies 2050a, and the three sleeves 2054b at bottoms of the telescopic assemblies 2050b. In another embodiment, as shown in FIG. 7B, three metal seats 2056 set on the tops of three branches of the electric wire 208a whereby the three metal seats 2056 are respectively attached to the bottoms of the three sleeves 2054b of the telescopic assemblies 2050b.

The under test zone 202 of the measuring instrument 1 also sets an annular shape cooling chip 307 (also known as thermoelectric cooler, semiconductor refrigeration, heat pump, etc.) surrounds the electrodes 205, 210. The cooling chip 307 consists of a plurality of cooling dies made from different types of materials such as Bismuth telluride packaged into two electrically insulating ceramic plates on both sides. When DC current flows through the chip 307 operated by the Peltier effect to create a heat flux between the junction of adjacent two dies and brings heat from one side to the other, so that one side gets cooler while the other gets hotter. The hot side is attached to a heat sink so that it remains at ambient temperature, while the cool side goes below room temperature. The present disclosure uses the annular cooling chip 307, bottom side of the annular plate of the cooling chip 307 functions as a heating (heat dissipating) surface and tightly attached to the corresponding grooved bottom surface of the carrier plate 201, and upper side of the annular plate functions as a cooling (heat absorbing) surface and has the same high with the outer surface of the under test zone 202. Practical application of the cooling chip may also use other shapes. Two electric wires 208b are electrically connected with the cooling chip 307 using a plug 209b connected to an external control power supply (not shown), to supply the power to the cooling chip 307. The electric wires 208b pass through the carrier plate 201, the heat sink fin 306a and the wall hole 104 to an outside of the rear section 102 of the shell portion 10.

A thermal sensor (e.g., thermistors or thermocouples) (not shown) is stuck on the cooling surface of the cooling chip 307; through the thermal sensor connecting the temperature control circuit (not shown) and setting the temperature of the cooling surface via the temperature monitor (not shown), the cooling surface is maintained at low temperature (e.g., 10° C. or 20° C.) during measurement. Heat released from LED light source 203 absorbed on the under test zone 202 is absorbed by the cooling surface. So that, the LED light source 203 is measured at a controlled low temperature, thereby the LED light source 203 is prevented from being damaged by excessive temperature rise. In order to achieve above mentioned low temperature measurement to prevent the heating surface of the cooling chip 307 from being unable to dissipate the heat from the cooling surface whereby the temperature will rise and the thermal energy will backflow to the cooling surface, the present disclosure discloses the use of the carrier plate 201 to conduct the heat released from heating surface of the cooling chip 307 to the heat sink fin 306a. In addition, in the rear section 102 of the shell portion 10 close to the inner wall surface of the bottom there is provided with a fan 308, wherein the fan 308 blows the cold air from outside into the heat sink fin 306a; the spiral direction of the spiral heat sink fin 306a is consistent with the rotation direction of the fan 308, enabling the cooling airflow easily lead to the heat sink fin 306a to remove heat therefrom.

When the measuring instrument 1 has not been inserted into the integrating sphere, the fan 308 sucks the cooling airflow via a plurality of lateral air inlets 310a, wherein the lateral air inlets 310a partially surround the fan 308 and are located around the lower side of the rear section 102. When the measuring instrument 1 inserted into the integrating sphere, the fan 308 sucks the cooling airflow via both a plurality of axial air inlets 310b located at the bottom side of the rear section 102 and also the lateral air inlets 310a. At air outlet of the fan 308 there is a tapered wind guider 309 toward the heat sink fin 306a; the outlet of the wind guider 309 covers the axial free end of the heat sink fin 306a, in order to accelerate and guide the converged cooling airflow to the heat sink fin 306a and the carrier plate 201. An endothermic airflow of the neighbor heat sink fin 306a via the spacing between the side edge of the heat sink fin 306a and the inner wall of the upper stage section 101 is guided into the annular channel formed between the inner wall surface of the upper stage section 101 and the outer wall surface of the wind guider 309. Then via a plurality of air outlets 311 partly defined in the wall surface of the rear section 102, the endothermic airflow released from the LED light source 203 and the heating surface of the cooling chip 307 is discharged out of the integrating sphere.

When operating the measuring instrument 1 to measure the LED light source 203, first step is to turn on the vacuum pump 50, and then place the LED light source 203 on the under test zone 202, make the central bottom side of the LED light source 203 abut on the air hole 204, and make the base positive and negative electrode plates 2032, 2033 abut against to the at least one pair of electrodes 205, 210 corresponding protruding thimbles 2052 of the measuring instrument 1. The light emitting surface 2031 of the LED light source 203 is at the top side thereof, which is opposite to the bottom side of the base positive and negative electrode plates 2032, 2033. Through a vacuum force provided by the vacuum pump 50, the LED light source 203 is attached and fixed on the under test zone 202 via the vacuum force in the air hole 204. Simultaneously, at least one pair of the thimble 2052 with different polarity tightly contacts on the base positive and negative electrode plates 2032, 2033 respectively of the LED light source 203. After the predetermined temperature of the cooling surface of the annular cooling chip 307 is set and the fan 308 is turned on, the external power is supplied to the cooling chip 307; then the measuring instrument 1 is inserted into the entrance of the integrating sphere. Adjust and stabilize the external control power until the operating current and voltage of the LED light source 203 meets the specification; then, turn on the power for lighting the LED light source 203 inside the integrating sphere. Confirm the temperature of the cooling surface reaches stability state by the temperature display, and startup the optical and electrical properties automatic measurement system of the LED light source 203. When measurement is completed, turn off the external control power to extinguish the LED light source 203, then remove the measuring instrument 1 from the integrating sphere, and remove the LED light source 203, continue to place another LED light source 203 on the under test zone 202 for measurement.

Compared to the conventional LED light source measuring instruments 1a, 1b, since the present embodiment is via a vacuum pump 50 to provide the vacuum force at the bottom of the LED light source 203, the present disclosure achieves the LED light source 203 not only closely attached and easily positioned on the most front surface of the measuring instrument 1, but also electrically connected to the base positive and negative electrode plates 2032, 2033, completely excluding the light blocking shortcoming of the conventional measuring instruments 1a, 1b, and completely avoiding the temperature rise of the LED light source 203 which may causes measurement uncertainty and destructive risk; moreover the measurement instrument 1 of the present disclosure has a more simplified structure than conventional measuring instruments 1a, 1b. In present disclosure, power can be supplied to any SMT type LED light source with base positive and negative electrode plates 2032, 2033; the present disclosure can be used to measure different sizes, shapes, structures and types of the LED light source without any restriction, ensure the excellent measurement quality and extremely versatile of the LED light source measuring instrument 1.

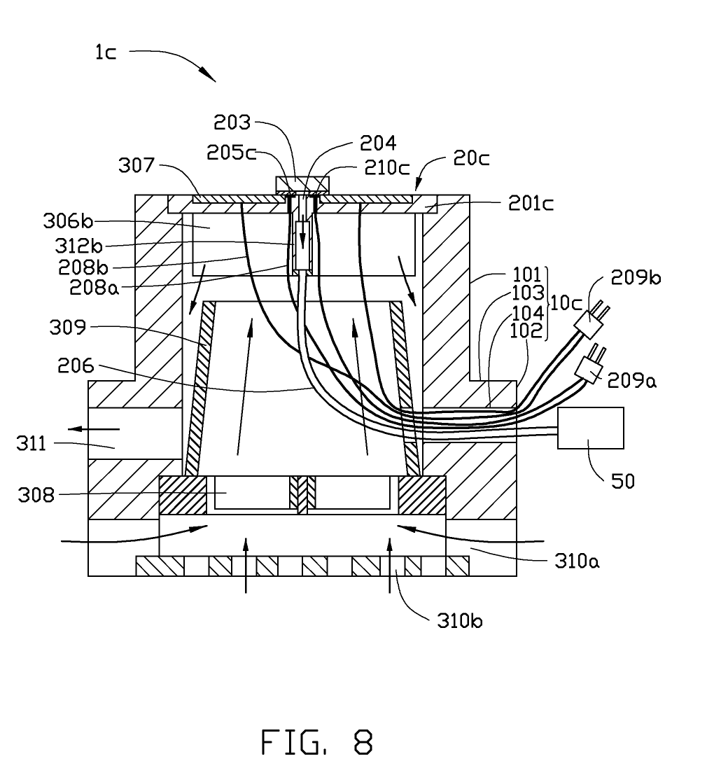

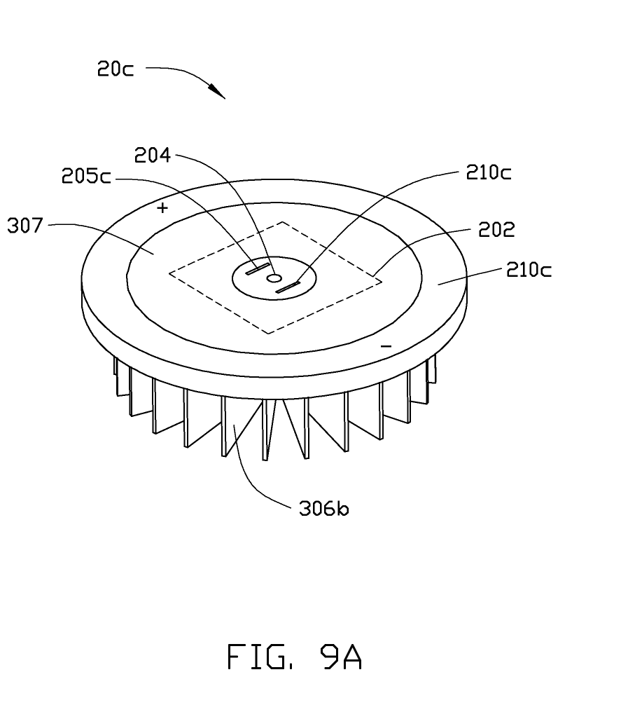

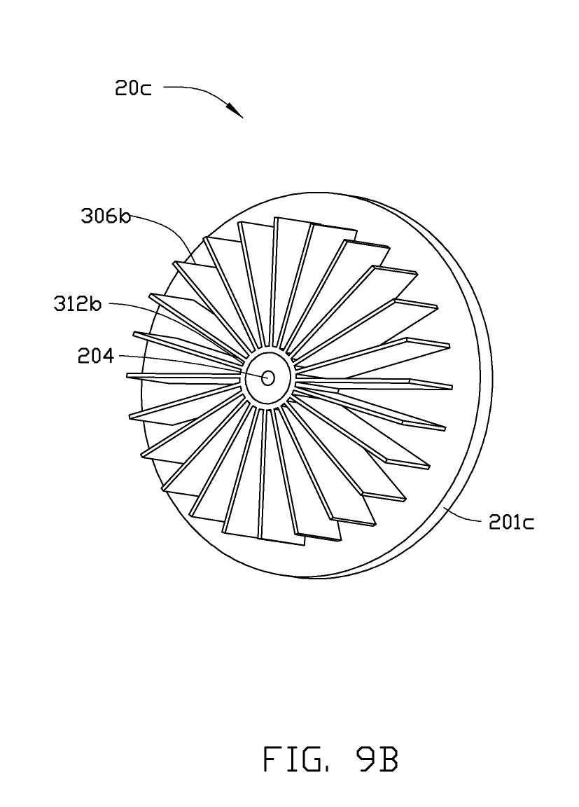

FIG. 8 is an assembled schematic cross-sectional view of the second embodiment. FIGS. 9A and 9B respectively are a top and a bottom perspective view of the test portion of the measuring instrument of FIG. 8. The main difference between the present embodiment and the foregoing embodiment is that: To simplify the pairs of electrodes 205, 210 as two sheet metal strips laid and slightly protrude out of the surface of a carrier plate 201c to form a pair of electrodes 205c, 210c which electrically insulating with the carrier plate 201c. Practical application of the sheet metal electrodes may also use other shapes. The cooling surface of the cooling chip 307 is arranged on the same plane with the electrodes 205c, 210c. Therefore, when using the vacuum force to attach and fix the LED light source 203 on the under test zone 202, an electrical connection of the LED light source 203 with electrodes 205c, 210c is also achieved.

Further, the pair of the sheet metal strip electrodes 205c, 210c is electrically connected to the external control power supply via two electric wires 208a directly passing through the carrier plate 201c and led out of a shell portion 10c via a heat sink fin 306b. That is, the wires 208a are unnecessary to be led out through the opening end of a central cylinder 312b. Therefore, the diameter of the central cylinder 312b can be decreased, thereby increasing the density of the heat sink fin 306b close to the center of the under test zone 202. Such design increases the efficiency of heat dissipation, also enables a direct connection of the flexible tube 206 with the opening of the central cylinder 312b, whereby the cylinder lid 315 of the first embodiment can be eliminated in this embodiment.

Furthermore, in the present embodiment a radially extending straight plate heat sink fin 306b connected with the central cylinder 312b is proposed for substituting the radially extending spiral plate heat sink fin 306a connected with the central cylinder 312a, wherein the straight fin is more easily to manufacture and accordingly has a lower cost. To achieve the easier manufacture purpose, practical application of the heat sink fin may also use other types. For example, the different shapes of central cylinder and pin fin, louver fin, stack fin, etc. Obviously, the measuring instrument 1c in addition to achieve the same benefits as the forgoing embodiment and its advantages beyond the conventional technology, further has the streamline structure, to simplify the process and reduce the cost.

In the above embodiment the technical features and the reached effect of the present disclosure are clearly described, which include:
A LED light source measuring instrument is provided, which has a high precision ability to measure the optical and the electrical properties; vacuum force is used to easily attach and fix the SMT type LED on the under test zone; and the LED is powered by contacting between the base positive and negative electrode plates of the LED and the positive and negative electrodes of the measuring instrument. The LED light source is maintained at the most front surface of the measuring instrument, to overcome the light blocking shortcoming of the conventional measuring instrument, and to achieve high precision optical and electrical performance of the measuring instrument.

The present disclosure provides a LED measuring instrument which can maintain the LED light source under different temperature protected conditions to carry out the steady state optical and electrical measurement. Via the cooling chip positioned near the electrodes, the present disclosure provides high efficient heat dissipation and smoothes the path of the cooling airflow, whereby the heat released from the LED light source and the heating surface of the cooling chip can be exhausted out of the LED measuring instrument and the integrating sphere quickly. The quick release of the heat from the LED light source can effectively eliminate the measurement errors and risk of damage to the LED light source caused by rapid temperature rise of the LED light source.

The present disclosure provides an optical and electrical performance measuring instrument which can be applied to any sizes or types of SMT type LED, supply power to any SMT type LED light source with base positive and negative electrode plates, regardless of the size and type of the LED whether with the longitudinal or lateral positive and negative electrode plates; thus all the diversified SMT type LEDs measurement can be achieved by one LED measuring instrument of the present disclosure.

The present disclosure provides a SMT type LED measuring instrument with a simple structure, easy operation, without the positioning fixture with complex structure of the conventional measuring instrument. Thus can simplify the operation for installment and removal of the LED light source, achieve streamline the cost and simplify the process of the measuring instrument, and ensure the measurement quality and the long term reliability.

Although the present disclosure has been specifically described on the basis of this exemplary embodiment, the disclosure is not to be construed as being limited thereto. Various changes or modifications may be made to the embodiment without departing from the scope and spirit of the disclosure.

What is claimed is:

1. A LED (light emitting diode) light source measuring instrument for measuring characteristics of a LED light source, comprising:
a shell portion and a test portion, the shell portion supporting the test portion, the test portion including a carrier plate for placing the LED light source, a bottom surface of the LED light source with electrode plates is attached and positioned on a test zone of the carrier plate, a light emitting surface of the LED light source being away from the carrier plate;
wherein a conductive structure is set on the test zone to electrically connect with the electrode plates for supplying power to the LED light source;
at least one air hole set in the test zone near the LED light source;
a cooling chip set on the carrier plate near the air hole for controlling the temperature of the LED light source within a predetermined range; and
a vacuum suction device is in communication with the at least one air hole for providing a vacuum force on the test portion to secure the LED light source to the test zone.

2. The LED light source measuring instrument as claimed in claim 1, wherein the shell portion is a hollow cylinder and with at least one side opening, the carrier plate is located at the opening side, and the test portion comprises a heat sink fin extending from a side of the carrier plate opposite the LED light source.

3. The LED light source measuring instrument as claimed in claim 2, wherein an end of the shell portion away from the carrier plate is positioned with a fan for generating a cooling airflow to the heat sink fin.

4. The LED light source measuring instrument as claimed in claim 3, wherein the shell portion defines a plurality of air inlets located away from the carrier plate, the air inlets comprise a plurality of lateral and a plurality of axial air inlets, and the fan inhales the cooling airflow via the air inlets.

5. The LED light source measuring instrument as claimed in claim 3, wherein an air outlet of the fan has a tapered wind guider converging toward the heat sink fin.

6. The LED light source measuring instrument as claimed in claim 5, wherein the cooling airflow flow through an annular channel formed by an inner wall surface of the shell portion and an outer wall surface of the wind guider to reach a plurality of air outlets to leave the LED light source measuring instrument.

7. The LED light source measuring instrument as claimed in claim 2, wherein the carrier plate comprises a central cylinder, the vacuum suction device comprises a flexible tube and a vacuum pump, a space surrounded by the central cylinder is connected with the at least one air hole and the flexible tube, the heat sink fin is located around a periphery of a central cylinder and extends radially.

8. The LED light source measuring instrument as claimed in claim 1, wherein the conductive structure comprises at least one pair of electrodes positioned neighboring opposite sides of the at least one air hole and at a side of the carrier plate exposed outwardly.

9. The LED light source measuring instrument as claimed in claim 8, wherein the cooling chip is an annular shape and surrounds the at least one pair of electrodes.

10. The LED light source measuring instrument as claimed in claim 9, wherein the carrier plate defines a groove, a plurality of the cooling dies are packaged into two electrically insulating ceramic plates on both sides to form the cooling chip, one side of the annular plate of the cooling chip functions as a heating surface and tightly attached to a bottom of the groove of the carrier plate, and the other side of the annular plate of the cooling ship functions as a cooling surface, and the cooling surface has the same high with an outer surface of the test zone.

11. The LED light source measuring instrument as claimed in claim 8, wherein the at least one pair of electrodes of the conductive structure each comprises a telescopic assembly and at least one thimble, the telescopic assembly comprising a metal sleeve and a spring which is equipped inside the sleeve, the at least one thimble pressing the spring inside the sleeve, the sleeve having upper and lower ends, at least the upper end being with an opening, and the at least one thimble along with the spring axial stretching toward the opening.

12. The LED light source measuring instrument as claimed in claim 8, wherein each electrodes of the conductive structure is formed as a sheet metal strip fixedly attached on and electrically insulated from the carrier plate, the cooling surface of the cooling chip is arranged on the same plane with the at least one pair of electrodes.

13. The LED light source measuring instrument as claimed in claim 11, wherein the at least one pair of electrodes is electrically connected with two electric wires directly passing through the carrier plate, and the two electric wires are led outside the shell portion to form an electrical connection configured for electrically connecting with an external control power.
